(19) United States
(12) Patent Application Publication
(10) Pub. No.: US 2026/0082518 A1
(43) Pub. Date: Mar. 19, 2026

(54) FAR-EDGE SERVER WITH SINGLE-PHASE IMMERSION COOLING

(71) Applicant: ZT Group Int'l, Inc., Secaucus, NJ (US)

(72) Inventors: Rajiv LIMAYE, Bellevue, WA (US); Tommy LIN, Maspeth, NY (US); SunilKumar PINNU, Jersey city, NJ (US); Sruti CHIGULLAPALLI, Seattle, WA (US)

(73) Assignee: ZT Group Int'l, Inc., Secaucus, NJ (US)

(21) Appl. No.: 18/889,641

(22) Filed: Sep. 19, 2024

(51) Int. Cl. H05K 7/20

(52) U.S. Cl. CPC H05K 7/20772; H05K 7/20236; H05K 7/20263; H05K 7/20272

(57) ABSTRACT

Described herein is a wireless-telecom server for implementation proximate a remote radio-unit (RRU) (e.g., on a same pole as the RRU). The server includes an internal enclosure with wireless-telecom network cards and a dielectric liquid disposed therein. The server also includes pumps configured to circulate the dielectric liquid within the internal enclosure. The server further includes a network connection configured to communicate with a network, radio connection configured to communicate with the RRU, and a power connection configured to supply power to the server. The network connection, the radio connection, and the power connection pass through a wall of the internal enclosure. The server also includes fans configured to direct air around the internal enclosure. By configuring the server for placement proximate the RRU, a need for a server room near the RRU and/or a high number of long fiber-optic cable runs may be obviated.

### FIELD

This disclosure is directed to far-edge wireless-telecom servers.

### BACKGROUND

Telecom providers often place far-edge wireless-telecom servers in environmentally-controlled server rooms proximate remote radio-units (RRUs). For example, the server rooms may be at bases of towers that house the RRUs or at least within a small radius of the towers. While such implementations may work well for urban locations, they may not work well for remote locations. For example, in some remote locations, the RRUs may be at least five kilometers from a closest server room. As the connection between the servers and the RRUs often involves up to nine fiber-optic cables, long runs (e.g., in remote locations) may be cost prohibitive, and wireless coverage may suffer.

Furthermore, modern radio technologies often require very strict timing constraints. Such constraints may be hard to achieve via long distances between servers and RRUs. Accordingly, servers are increasingly being implemented closer and closer to RRUs. Building environmentally controlled enclosures for such servers (e.g., sheds, buildings, etc.) in many locations is simply not feasible or economically prohibitive.

### SUMMARY

A wireless-telecom server is described herein. The server includes an internal enclosure with one or more wireless-telecom network cards disposed therein. The internal enclosure is filled with a dielectric liquid. The server also includes one or more pumps configured to circulate the dielectric liquid within the internal enclosure. The server further includes a network connection configured to communicate with a wireless-telecom network, a radio connection configured to communicate with one or more RRUs, and a power connection configured to supply power to the wireless-telecom server. The network connection, the radio connection, and the power connection pass through a wall of the internal enclosure. The server also includes one or more fans configured to direct air around the internal enclosure.

A wireless-telecom server chassis is also described herein. The chassis includes an internal enclosure configured to contain a wireless-telecom server board and to be filled with a dielectric liquid. The chassis also includes one or more pumps configured to circulate the dielectric liquid within the internal enclosure. The chassis further includes one or more network ports disposed through a wall of the internal enclosure, one or more radio ports disposed through the wall of the internal enclosure, and a power port disposed through a wall of the internal enclosure. The chassis also includes one or more fans configured to direct air around the internal enclosure.

A method of assembling a wireless-telecom server is also described herein. The method includes obtaining the wireless-telecom server chassis described above. The method also includes securing a wireless-telecom server board within the internal enclosure and connecting the network ports, the radio ports, and the power port to the wireless-telecom server board. The method further includes filling the internal enclosure with a dielectric liquid and sealing the internal enclosure.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example implementation of a far-edge wireless-telecom server with single-phase immersion cooling in accordance with this disclosure.

FIG. 2 illustrates an example schematic of a far-edge wireless-telecom server with single-phase immersion cooling in accordance with this disclosure.

FIG. 3 illustrates an example fluid flow within an interior of an internal enclosure of a far-edge wireless-telecom server with single-phase immersion cooling in accordance with this disclosure.

FIG. 4 illustrates an example of an interior of an internal enclosure of a far-edge wireless-telecom server with single-phase immersion cooling in accordance with this disclosure.

FIG. 5 illustrates an example of a chassis of a far-edge wireless-telecom server with single-phase immersion cooling in accordance with this disclosure.

FIG. 6 illustrates an example of a section view of the chassis of FIG. 5 in accordance with this disclosure.

FIG. 7 illustrates an example method of assembling a far-edge wireless-telecom server in accordance with this disclosure.

### DETAILED DESCRIPTION

### Overview

Telecom providers are often faced with limited options for providing connectivity to RRUs of remote locations. This is because traditional far-edge wireless-telecom servers have limited environmental tolerances. One option is to build server rooms at the bases of the antenna structures (e.g., towers) of the RRUs. Another option is to run the required cabling from the nearest server room to the RRUs, which is often over 5 km. Both options can be very costly for the providers. If the costs are prohibitive to implementing RRUs in such locations, the providers may simply decide to not provide coverage in such locations, which may be detrimental to consumers and the providers.

Described herein is a far-edge wireless-telecom server for implementation proximate a RRU (e.g., on a same pole as the RRU). The server includes an internal enclosure with one or more wireless-telecom network cards. The internal enclosure is filled with a dielectric liquid. The dielectric liquid may be a non-conductive liquid configured to facilitate heat transfer between components within the internal enclosure and one or more walls of the internal enclosure. The server also includes one or more pumps configured to circulate the dielectric liquid within the internal enclosure. The server further includes at least one network connection configured to communicate with a network (e.g., telecom network), a radio connection configured to communicate with the RRU, and a power connection configured to supply power to the server. The network connection, the radio connection, and the power connection pass through a wall of the internal enclosure. The server also includes fans configured to direct air around the internal enclosure.

Far-edge, as used herein, refers to a location proximate end locations (e.g., IOT devices, cameras, RRUs, communication systems, etc.). In at least some cases, the far-edge refers to a computing layer or architecture that resides beyond an immediate edge (e.g., a near-edge) but remains geographically proximate to a data source or data sink. For example, far-edge devices may operate at a network's periphery. Far-edge devices may serve as gateways, routers, or edge servers and/or perform other computing functions. Such devices may facilitate data aggregation, filtering, preliminary analysis, predictive algorithms, or other functions before communicating data to or from other computing devices (e.g., central computing devices, cloud devices, data center devices, and the like). In many implementations, far-edge devices operate in resource-constrained environments, such as intermittent connectivity environments or high latency environments.

Often times, it may be desired to have servers be within a few meters or even a few centimeters from such end locations. Although this disclosure is directed to wireless technologies, the end locations may be any type of device that necessitates a network connection. Thus, the server and chassis described herein may be used to support a variety of technologies.

By configuring the far-edge server for placement proximate the RRU, a need for a server room and/or environmentally-controlled enclosure near the RRU (or other operating equipment) and/or a high number of long fiber-optic cable runs may be obviated. Accordingly, the far-edge server can be placed anywhere an RRU (or other operating equipment) is placed without undue cost and/or complexity.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example Implementation

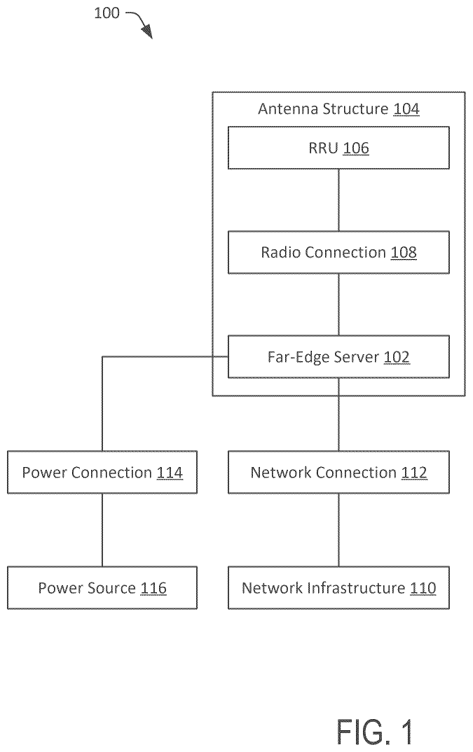

FIG. 1 illustrates an example of an implementation 100 of a far-edge wireless-telecom server with single-phase immersion cooling (e.g., far-edge server 102). In the implementation 100, the far-edge server 102 is included within an antenna structure 104 that also includes an RRU 106. The antenna structure 104 may include a pole, tower, antenna, fake tree, or other structure. The antenna structure 104 may be sole purpose or multi-purpose (e.g., a telephone or electrical pole). The far-edge server 102 may be mounted anywhere on the antenna structure 104 or proximate the antenna structure 104 (e.g., near a base of the antenna structure 104). The RRU 106 may include any number of antennas, radios, transceivers, and associated circuitry. The RRU 106 may be configured to generate and receive cellular radio transmissions and receptions (e.g., 5G or 6G).

Connecting the far-edge server 102 to the RRU 106 may be a radio connection 108. The radio connection 108 may include one or more fiber-optic connections (e.g., fiber-optic cables). For example, there may be nine fiber-optic cables connecting the far-edge server 102 to the RRU 106. In some implementations, the radio connection 108 may include electrical cables (e.g., CAT5, coaxial, or multi-conductor cables) or some combination of optical and electrical cables.

The far-edge server 102 may be connected to a network infrastructure 110 (e.g., edge server or wireless provider network) via a network connection 112. The network connection 112 may include electrical cables (e.g., CAT5, coaxial, or multi-conductor cables). In some implementations, the network connection 112 may include fiber-optic or some combination of optical and electrical cables.

A power connection 114 may be connected to the far-edge server 102 to provide power to the far-edge server 102. The power connection 114 may connect the far-edge server 102 to a power source 116 (e.g., a utility, battery, solar, or local power generation). The power source 116 may also power the RRU 106 and/or any other components of the antenna structure 104.

### Example Far-Edge Server Schematic

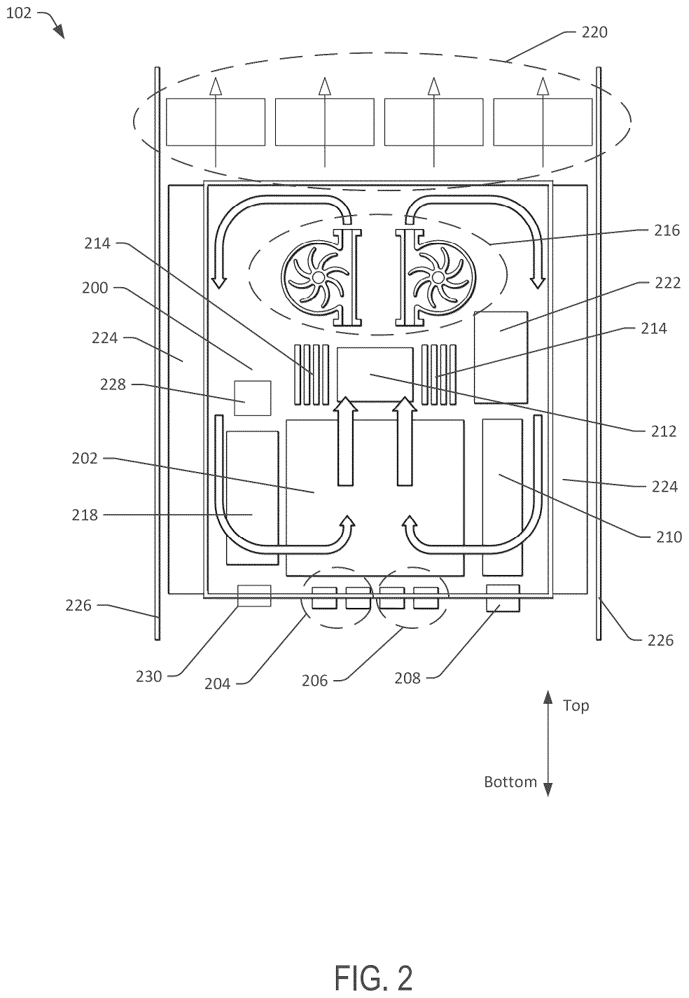

FIG. 2 illustrates a schematic of the far-edge server 102. The far-edge server 102 contains an internal enclosure 200 that is filled with a dielectric liquid (e.g., heat-transfer fluid, coolant). Because the far-edge server 102 is not configured to have the dielectric liquid pass through a phase change, it may be considered a single-phase immersion cooled system. Sealed in the sense of this disclosure means that the dielectric liquid cannot escape the internal enclosure 200 once the internal enclosure 200 is configured to be sealed. There may be means for filling the internal enclosure 200 with the dielectric liquid and/or for accessing an interior of the internal enclosure 200. For example, the internal enclosure 200 may have a removeable lid (not shown) to install various components therein, fill the internal enclosure 200 with the dielectric liquid, and/or access the interior of the internal enclosure 200 for maintenance.

The internal enclosure 200 may also contain a pressure relieving device 228. The pressure relieving device 228 may be a diaphragm device configured to expand or contract with a pressure differential between an interior of the internal enclosure 200 and an exterior of the internal enclosure 200. The pressure relieving device 228 may also be a membrane device configured to allow air to pass therethrough to equalize pressure. The pressure relieving device 228 may also be a one-way valve or pop-off valve. The pressure relieving device 228 may be disposed anywhere on an exterior wall of the internal enclosure (e.g., a top wall where an air mass may exist). In some implementations, the internal enclosure 200 may be configured to accommodate the pressure differentials without mitigating them. For example, an air volume may be maintained within an interior of the internal enclosure 200.

Within the internal enclosure 200 is one or more network cards 202 (e.g., wireless-telecom network cards, 5G cards). The network cards 202 are configured to facilitate the network connection 112 and the radio connection 108. To do so, the internal enclosure 200 may include one or more network ports 204 and one or more radio ports 206 passing through a wall of the internal enclosure 200. The ports may be part of the network cards 202 (e.g., the network cards 202 may be sealed to the wall of the internal enclosure 200), or the ports may be connected to the network cards 202 via internal connections (e.g., the ports are intermediary connections or bulkheads through the wall of the internal enclosure 200). In some implementations, the network ports 204 and/or the radio ports 206 may be bulkheads configured to run cables therethrough. Furthermore, the network and radio ports may be on different walls of the internal enclosure 200.

To power the far-edge server 102, a power port 208 may also be disposed through a wall of the internal enclosure 200 (e.g., the same wall as the network and radio ports or a different wall). The power port 208 may be connected to a power supply 210 within the internal enclosure 200 that is configured to power various components within the internal enclosure 200. Similar to the network and radio connections, the power port 208 may be an intermediary connection (e.g., the power supply 210 connects to one side of the power port 208 and the power source 116 is connected to another side of the power port 208). In some implementations, the power supply 210 may include the power port 208 (e.g., the power supply 210 may be sealed to the wall of the internal enclosure 200).

The far-edge server 102 may include a processing unit 212 configured to execute various operations of the far-edge server 102. The processing unit 212 may be one or more processors, one or more central processing units (CPUs), one or more graphics processing units (GPUs), one or more application-specific integrated circuits (ASICs), one or more controllers or microcontrollers, one or more ladder logic controllers, one or more other types of control logic, or some combination thereof. For example, the processing unit 212 may communicate with the network cards 202 to send/receive data from the network infrastructure 110 via the network connection 112 and to send/receive data from the RRU 106 via the radio connection 108.

To facilitate the operation of the processing unit 212 and the network cards 202, the far-edge server 102 may also include one or more memory modules 214. The memory modules 214 may contain instructions executable by the processing unit 212 to perform the various functions described herein. For example, the memory modules 214 may include dual in-line memory modules (DIMMS) and may be disposed on one or both sides of the processing unit 212.

The far-edge server 102 also includes one or more pumps 216 configured to circulate the dielectric fluid around the internal enclosure 200. The pumps 216 may be within the internal enclosure 200 (e.g., as immersion pumps) or be external to the internal enclosure 200 (e.g., with influent and effluent plumbing through a wall of the internal enclosure 200). By implementing two of pumps 216, symmetrical directed flows within the internal enclosure 200 may be achieved. Furthermore, two pumps may enable redundancy in case one pump fails. The pumps 216 may be configured to direct effluent flows towards the network cards 202 along the walls of the internal enclosure 200 and receive influent flows from an interior of the internal enclosure 200 (e.g., after passing over/around the processing unit 212). The flow patterns within the internal enclosure 200 may vary without departing from the scope of this disclosure.

The far-edge server 102 further includes a heater 218. The heater 218 may be a resistive element or other type of heater configured to heat the dielectric liquid within the internal enclosure 200.

The far-edge server 102 also includes one or more fans 220 that are configured to force air past an exterior of the internal enclosure 200. The fans 220 may be configured to direct air in a bottom to top direction, as shown, in order to follow natural convection currently. The fans 220 may also be configured to direct air in the opposite direction (e.g., top to bottom) or any other direction.

The fans 220 may be international protection (IP) 67 and/or network equipment-building system (NEBS) class 4 compliant since the far-edge server 102 is configured to be disposed in an outside environment. For example, the far-edge server 102 may be configured to be disposed in a hostile environment where it may experience extremely low temperatures, extremely high temperatures, high wind, vibration, radiation, direct sun, absence of light, rain, snow, hail, and the like. In some cases, the environment can change rapidly.

It should be noted that the far-edge server 102 may also have an IP 67 and/or NEBS class 4 rating. The internal enclosure 200 may enable the components therein to not have such a rating (e.g., due to them being sealed from the environment); however, the far-edge server 102, as a whole, may have a high environmental resistance rating (e.g., IP 67, NEBS class 4).

To control the pumps 216, the heater 218, and the fans 220, the far-edge server 102 may also include a controller 222. The controller 222 may receive information from one or more temperature sensors (e.g., an internal temperature probe and/or an external temperature probe) indicating an internal and/or external temperature of the internal enclosure 200 and/or the processing unit 212. Based on information from the temperature sensors, the controller 222 may determine operations of the pumps 216, the heater 218, and the fans 220 to maintain the dielectric fluid within a temperature range. For example, the controller 222 may be configured to maintain the dielectric fluid above a pre-set temperature using the heater 218 (e.g., above −5 degrees C). The controller 222 may also be configured to maintain the dielectric fluid below another pre-set temperature using the pumps 216 and/or the fans 220. The controller 222 may also receive data about operations of the processing unit 212 and/or the network cards 202 (e.g., utilization rate, percentage of capabilities being used) and determine speeds of the pumps 216 and/or the fans 220. There may be a fan connection 230 between the controller 222 and the fans 220 that runs through a wall of the internal enclosure 200. In some implementations, the fans 220 may be independently controlled (e.g., without the controller 222) and may, thus, not necessitate the connection 230 through a wall of the internal enclosure 200.

To help facilitate cooling of the dielectric fluid, the internal enclosure 200 may have exterior fins 224 disposed on one or more exterior sides of the internal enclosure 200. The fans 220 may be configured to direct air over/around the exterior fins 224. The internal enclosure may also have interior fins (not shown) disposed on one or more interior sides of the internal enclosure 200. The fins may be any shape or configuration. The interior fins may increase heat transfer between the dielectric liquid and walls of the internal enclosure 200, and the exterior fins 224 may increase heat transfer between the walls of the internal enclosure 200 and an environment of the far-edge server 102.

An external enclosure 226 may surround the exterior fins 224. The fans 220 may be configured to force air between an exterior of the internal enclosure 200 and an interior of the external enclosure 226 (e.g., over the exterior fins 224). The external enclosure 226 may have open ends (e.g., one proximate the fans 220 and one opposite the fans 220) such that the forced air can enter and exit spaces between the exterior fins 224. As such, the external enclosure 226 may have four sides that form a rectangular interior in which the fans 220 and the internal enclosure 200 may be disposed.

### Example Fluid Flow

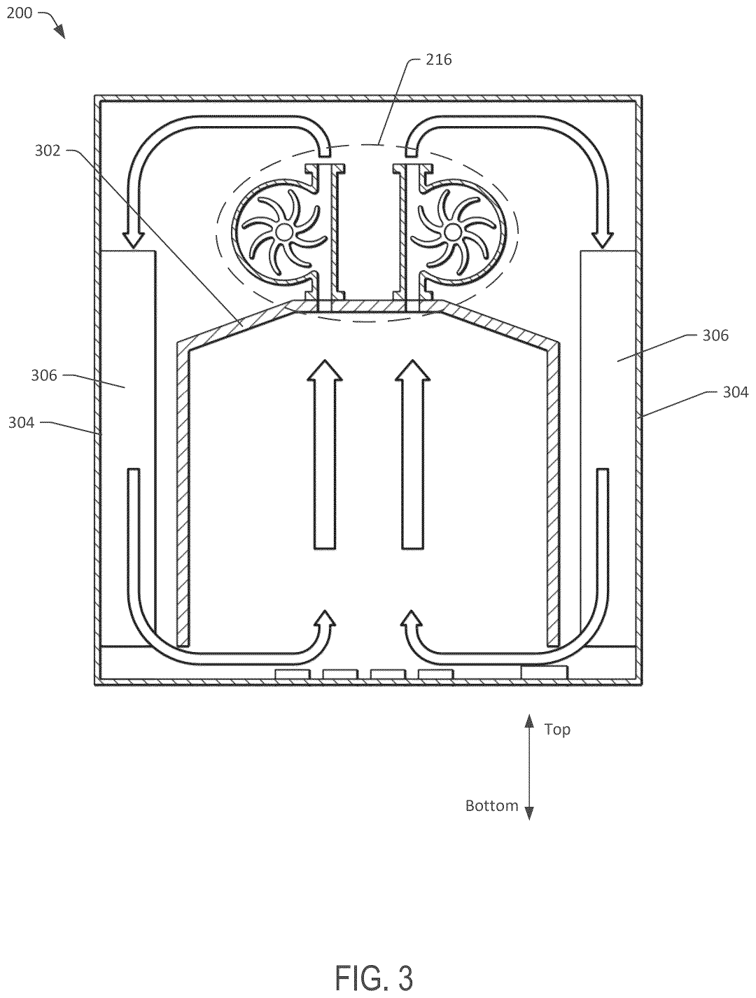

FIG. 3 illustrates an example of the internal enclosure 200 and an example fluid flow therein. Many of the components within the internal enclosure 200 have been removed for simplicity.

A fluid cap 302 may be disposed within an interior of the internal enclosure 200. The fluid cap 302 may be configured to direct flow of the dielectric fluid within the internal enclosure 200.

Heat generating components (e.g., the processing unit 212, the memory modules 214, and/or the network cards 202) may be disposed within an interior of the fluid cap 302 (e.g., a middle portion of the internal enclosure 200). The pumps 216 may be configured to draw the dielectric fluid from the interior of the fluid cap 302 (e.g., after gathering heat from the heat generating components) and force the dielectric fluid towards side walls 304 of the internal enclosure 200 and down the side walls 304 towards a bottom of the internal enclosure 200 (e.g., along an exterior of the fluid cap 302).

The side walls 304 may be configured to facilitate heat transfer from the dielectric fluid. For example, the side walls 304 may include interior fins 306 on interior sides of the side walls 304. The interior fins 306 increase a surface area of the side walls 304 such that heat from the dielectric fluid may transfer to the side walls 304 more rapidly. In some implementations, the interior fins 306 may also be on other walls of the internal enclosure 200 (e.g., front or back walls).

To facilitate desired flow patterns, the fluid cap 302 may be configured to direct effluent flows from the pumps 216 towards and down the side walls 304. The fluid cap 302 may also be configured to draw the dielectric fluid from the bottom of the internal enclosure 200 towards influent flows of the pumps 216. In some implementations, the flows may be reversed (e.g., the effluent flows may be within the interior of the fluid cap 302 and the influent flows may be around the fluid cap 302).

The fluid cap 302 may vary in size, shape, orientation, and/or configuration without departing from the scope of this disclosure. For example, the fluid cap 302 may be any structure capable of creating desired flow patterns within the internal enclosure 200. The pumps 216 may be connected to the fluid cap 302 or be offset therefrom.

### Example Internal Enclosure

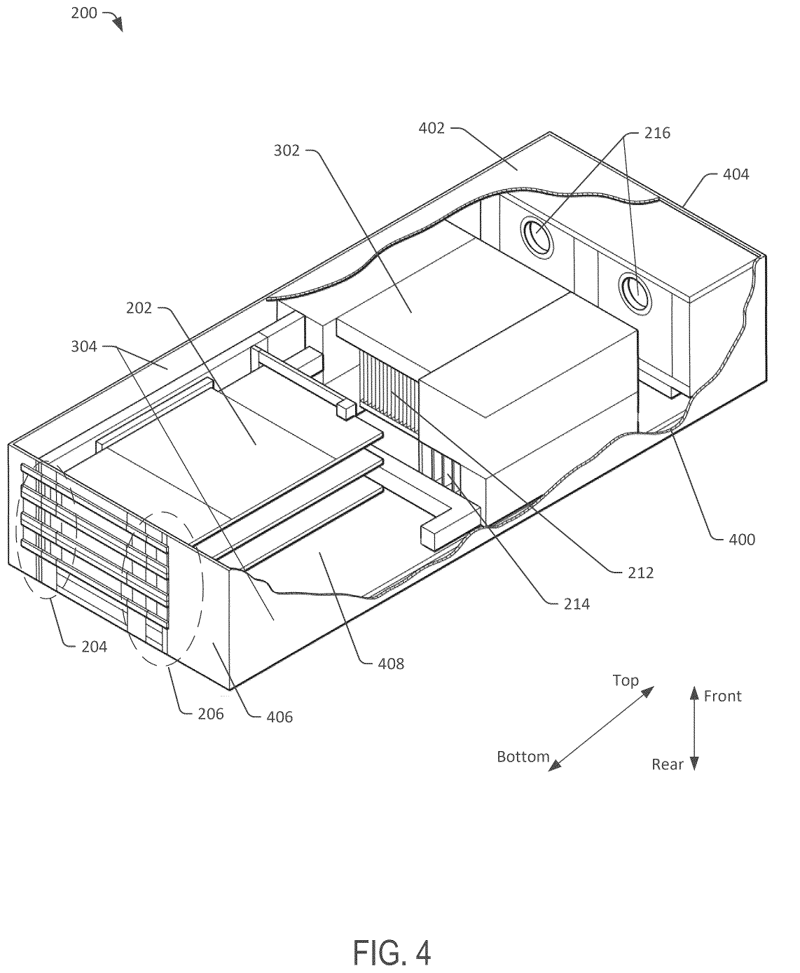

FIG. 4 illustrates an example of the internal enclosure 200 including various components disposed therein. The components may be rearranged, added to, or removed without departing from the scope of this disclosure.

The internal enclosure 200 may include a plurality of walls. For example, the internal enclosure 200 may include a rear wall 400 configured to be proximate the antenna structure 104, the side walls 304, a front wall 402 opposite the rear wall 400, a top wall 404 configured to face up when mounted on the antenna structure 104, and a bottom wall 406 configured to face down when mounted on the antenna structure 104.

Disposed through the bottom wall 406 (e.g., on a first side of the far-edge server 102) may be the network ports 204, the radio ports 206, and the power port 208 (not shown). In other words, the ports may be opposite the fans 220. By having the ports through the bottom wall 406, further environmental protection may be afforded (e.g., the ports may be shielded by the rest of the far-edge server 102).

A plurality of the components within the internal enclosure 200 may be disposed on and/or connected to a server board 408. For example, the network cards 202 may be attached to a first side of the server board 408 (e.g., proximate the bottom wall 406), the pumps 216 may be disposed on a second side of the server board 408 opposite the first side (e.g., proximate the top wall 404), and the processing unit 212 and the memory modules 214 may be disposed between the first and second sides of the server board 408. The network cards 202 may be stacked on one another and connected to a board connected to the server board 408 (e.g., at a right angle).

As discussed above, the internal enclosure 200 may also include the fluid cap 302 that is configured to direct flow of the dielectric liquid to/from the pumps 216. The fluid cap 302 may include any number of parts and cover any components. Again, the fluid cap 302 may be configured to direct effluent (or influent) flows from the pumps 216 towards walls of the internal enclosure 200 (e.g., the side walls 304 and/or the front wall 402) and towards the bottom wall 406. By doing so, the network cards 202 may receive the dielectric liquid at its coolest temperature (the network cards 202 may have a lower temperature tolerance than the processing unit 212 and/or the memory modules 214). The fluid cap 302 may also be configured to direct flows from around the network cards 202 across the processing unit 212 and the memory modules 214 and back to the pumps 216. Thus, flow of the dielectric fluid may go from the pumps 216, to the network cards 202, to the processing unit 212 and memory modules 214, and back to the pumps 216. Other flow configurations may be used without departing from the scope of this disclosure, however.

In the present disclosure, the terms, “influent” and “effluent,” refer broadly to the flow of a fluid (e.g., the dielectric fluid) and corresponding structures. For example, the term “influent” may imply the flow of fluid moving, or arranged to move, into a manifold, pump, line, or other structure, and the term “effluent” may imply the flow of fluid moving, or arranged to move, out of a manifold, pump, line, or other structure. The fluid moving into the structures (e.g., “influent”) may be the same fluid or a different fluid than that moving out of the structures. The terms, “influent” and “effluent,” in some cases, imply the flow of fluid moving, or arranged to move, in a particular direction (e.g., up, down, right, left, forwards, backwards, or the like). Furthermore, these terms may imply the flow of liquid through or across a boundary (e.g., a glycol moving through, into, or out of a pump, manifold, a chamber, a canister, a reservoir, or the like). Structures such as hoses, pipes, manifolds, quick disconnects, blind connectors, pressure fittings, compression fittings, and others facilitate the influent and effluent movement or flows of fluids, as further described in the present disclosure.

### Example Chassis

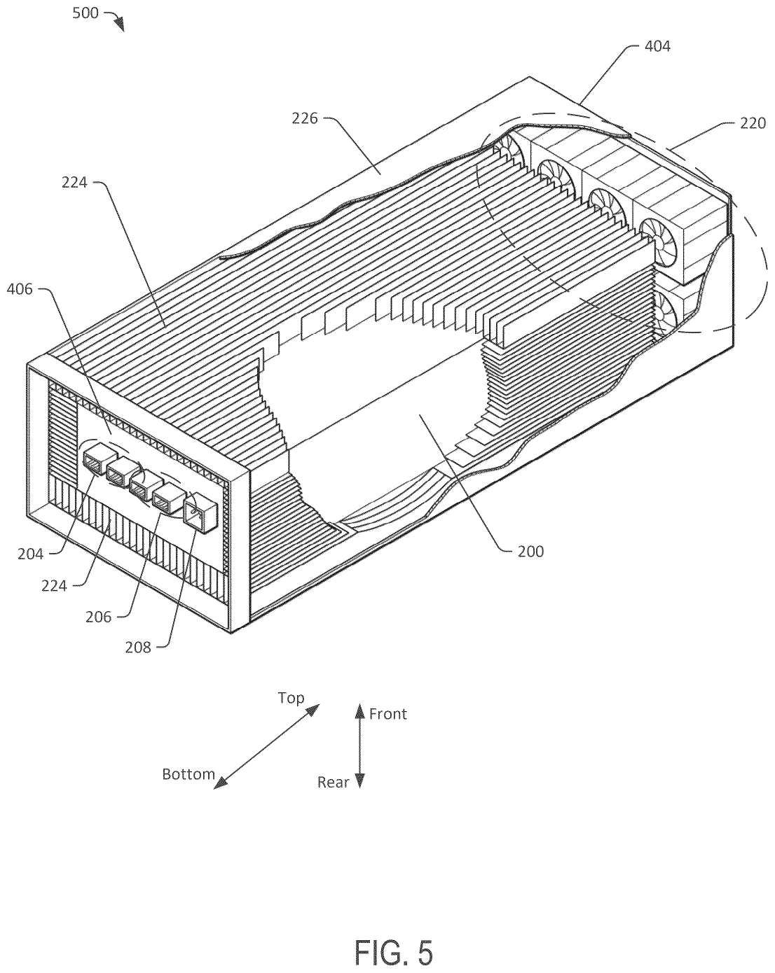

FIG. 5 illustrates an example of a server chassis 500 including the external enclosure 226 surrounding the exterior fins 224 of the internal enclosure 200 and the fans 220. Although the exterior fins 224 are illustrated on four sides of the internal enclosure 200, they may be disposed on any number of sides. The external enclosure 226, the internal enclosure 200, and the fans 220 (e.g., without the internal components of FIG. 3) may form the server chassis 500. The internal enclosure 200 of the server chassis 500 may then be filled with the server board 408 and the other components connected thereto to form the far-edge server 102.

The fans 220 may be disposed near the top wall 404 of the internal enclosure 200 (e.g., on a first side of the far-edge server 102) and directed to flow air towards the bottom wall 406 of the internal enclosure 200. In conjunction with the flow of the dielectric fluid discussed above (e.g., down along the walls), the internal enclosure 200 may act as a crossflow heat exchanger, which may enable better cooling of the dielectric fluid. The fans 220 may direct air in the opposite direction (e.g., from the bottom wall 406 towards the top wall 404 without departing from the scope of this disclosure.

As discussed above, the external enclosure 226 may enable air flow generated by the fans 220 to be restricted to a space between the internal enclosure 200 and the external enclosure 226. By doing so, air flow is restricted to flowing across the exterior fins 224, which may enable more efficient cooling of the dielectric fluid.

### Example Chassis Cross-section

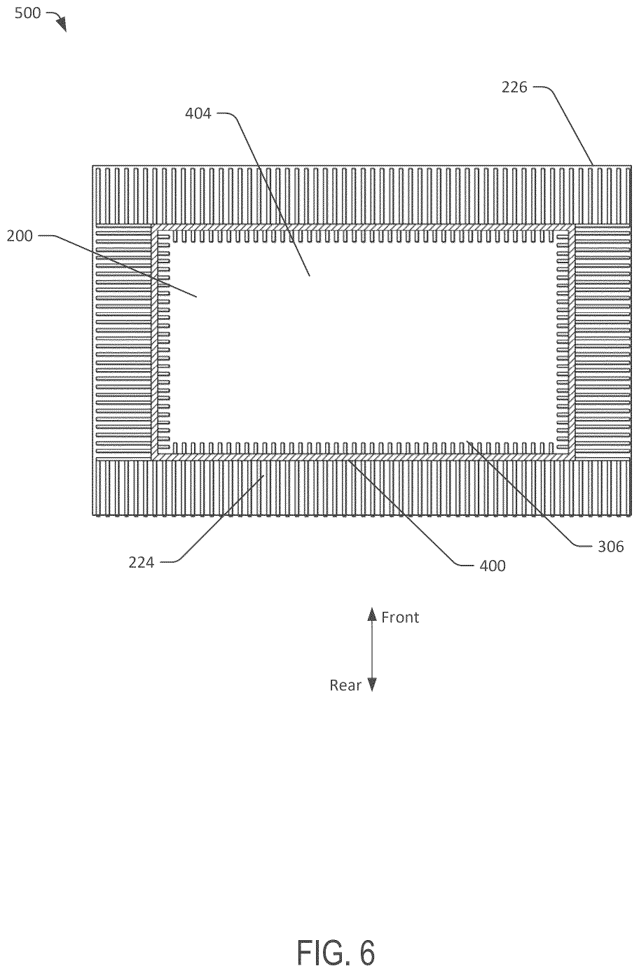

FIG. 6 illustrates an example of a cross-section of the server chassis 500. The server chassis 500 includes the internal enclosure 200 forming a space for the various internal components of the far-edge server 102. In the illustrated example, the internal enclosure 200 has the interior fins 306 that are configured to transfer heat from the dielectric fluid to walls of the internal enclosure 200. The internal enclosure 200 also has the exterior fins 224 that are configured to transfer heat from the walls of the internal enclosure 200 to air being forced over them by the fans 220 (not shown). The interior fins 306 may be smaller than the exterior fins 224. The internal enclosure 200 may have mounting provisions (not shown) for the server board 408 to mount the server board 408 above the interior fins 306. In some implementations, the interior fins 306 may not be disposed on one or more walls (e.g., the rear wall 400 such that the server board 408 can be directly attached to the rear wall 400).

The fans 220 may be disposed in any configuration along or near the top wall 404. For example, the fans 220 may be disposed around a perimeter of the top wall 404 such that a majority of flow produced enters the space between the internal enclosure 200 and the external enclosure 226. In other words, the fans 220 may not be disposed towards a center of the top wall 404. For example, the fans 220 may be arranged in two rows that are separated in the front-rear direction.

### Example Method

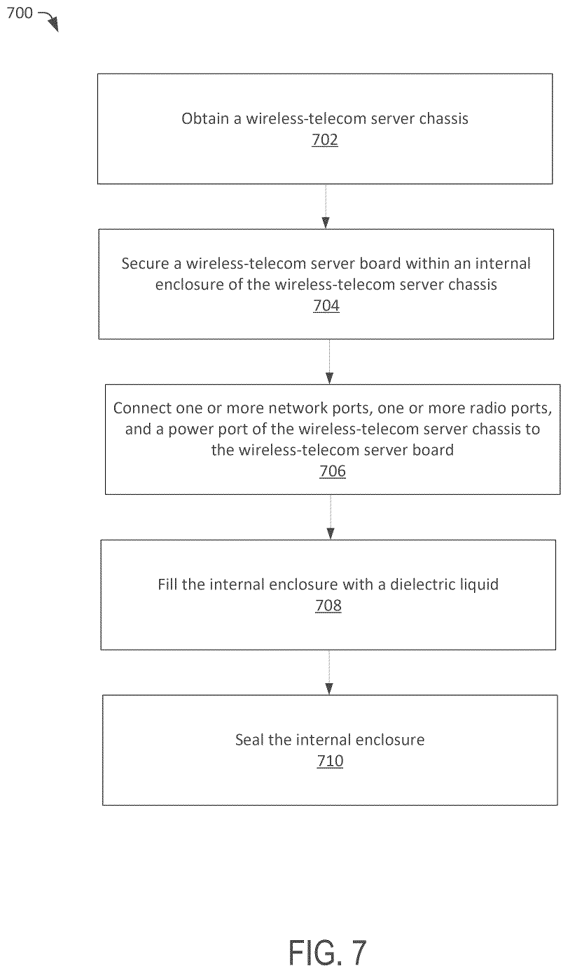

FIG. 7 illustrates an example method 700 of assembling a far-edge wireless-telecom server. The following steps may be rearranged, combined, and/or split without departing from the scope of this disclosure.

At 702, a wireless-telecom server chassis is obtained. For example, the server chassis 500 may be obtained.

At 704, a wireless-telecom server board is secured within an internal enclosure of the wireless-telecom server chassis. For example, the server board 408 may be secured within the internal enclosure 200. The server board 408 may be secured via screws, adhesive, or other fastening means to one or more walls of the internal enclosure 200. To do so, one or more portions of the internal enclosure 200 may first be removed.

At 706, one or more network ports, one or more radio ports, and a power port of the wireless-telecom server chassis are connected to the wireless-telecom server board. For example, interior sides of the network ports 204, the radio ports 206, and the power port 208 may be connected to the server board 408.

At 708, the internal enclosure is filled with a dielectric liquid. For example, the internal enclosure 200 may be filled with the dielectric liquid. In some implementations, the removed portions of the internal enclosure 200 may be reattached prior to filling and a fill port of the like may be used to fill the internal enclosure with the dielectric liquid.

At 710 the internal enclosure is sealed. For example, if a separate fill port is used the fill port may be sealed. If no separate fill port is used, the removed portions of the internal enclosure 200 may be reattached to seal the internal enclosure 200.

### EXAMPLES

Example 1: A far-edge server comprising: an internal enclosure; one or more wireless-telecom network cards disposed within the internal enclosure; a dielectric liquid within the internal enclosure; one or more pumps configured to circulate the dielectric liquid within the internal enclosure; a network connection configured to communicate with a wireless-telecom network; a radio connection configured to communicate with at least one remote radio-unit (RRU); a power connection configured to supply power to the wireless-telecom server ; and one or more fans configured to direct air around the internal enclosure, wherein the network connection, the radio connection, and the power connection pass through a wall of the internal enclosure.

Example 2: The far-edge server of example 1, wherein: the internal enclosure includes one or more seals between an interior of the internal enclosure and an exterior of the internal enclosure; and the seals are configured to provide at least one of: international protection (IP) 67 protection; or network equipment-building system (NEBS) class 4 protection.

Example 3: The far-edge server of example 1 or 2, wherein the fans are proximate a first side of the far-edge server and the network connection, the radio connection, and the power connection are on a second side of the far-edge server.

Example 4: The far-edge server of example 1, 2, or 3, wherein the internal enclosure further includes exterior fins on an exterior of the internal enclosure.

Example 5: The far-edge server of example 4, wherein the internal enclosure further includes interior fins on an interior of the internal enclosure.

Example 6: The far-edge server of example 4 or 5, wherein: the far-edge server further includes an external enclosure surrounding the exterior fins; and the fans are configured to force air between the internal enclosure and the external enclosure.

Example 7: The far-edge server of example 6, wherein the external enclosure is open on an end opposite the fans.

Example 8: The far-edge server of any preceding example, wherein the network connection and the radio connection includes network ports disposed through a wall of the internal enclosure.

Example 9: The far-edge server of example 8, wherein the network ports are disposed on the wireless-telecom network cards.

Example 10: The far-edge server of any preceding example, wherein the wireless-telecom network cards include a plurality of network cards that are stacked on one another.

Example 11: The far-edge server of any preceding example, wherein the far-edge server further includes a processing unit.

Example 12: The far-edge server of example 11, wherein: the pumps are disposed within the internal enclosure; and the processing unit is disposed between the pumps and the wireless-telecom network cards.

Example 13: The far-edge server of example 11 or 12, wherein the far-edge server further includes a fluid cap configured to direct one of influent flows or effluent flows from the pumps towards one or more walls of the internal enclosure and another of the influent flows or the effluent flows across the processing unit.

Example 14: The far-edge server of any preceding example, wherein the far-edge server further includes a heater configured to maintain the dielectric liquid above a pre-set temperature.

Example 15: The far-edge server of any preceding example, wherein the pumps are disposed within the internal enclosure.

Example 16: The far-edge server of any preceding example, wherein the internal enclosure further includes a pressure relieving device configured to mitigate a pressure differential between an interior of the internal enclosure and an exterior of the internal enclosure.

Example 17: The far-edge server of any preceding example, wherein the radio connection includes one or more fiber-optic connections.

Example 18: The far-edge server of any preceding example, wherein: the far-edge server includes an internal temperature probe; and the far-edge server is configured to control the pumps and the fans based on information received from the internal temperature probe.

Example 19: A far-edge server chassis comprising: an internal enclosure configured to contain: a far-edge server board; a dielectric liquid; one or more pumps configured to circulate the dielectric liquid within the internal enclosure; one or more network ports disposed through a wall of the internal enclosure; one or more radio ports disposed through the wall of the internal enclosure; a power port disposed through a wall of the internal enclosure; and one or more fans configured to direct air around the internal enclosure.

Example 20: The far-edge server chassis of example 19, wherein: the internal enclosure includes one or more seals between an interior of the internal enclosure and an exterior of the internal enclosure; and the seals are configured to provide at least one of: international protection (IP) 67 protection; or network equipment-building system (NEBS) class 4 protection.

Example 21: The far-edge server chassis of example 19 or 20, wherein the fans are proximate a first side of the far-edge server chassis and the network connection, the radio connection, and the power connection are on a second side of the far-edge server chassis.

Example 22: The far-edge server chassis of example 19, 20, or 21, wherein the internal enclosure further includes exterior fins on an exterior of the internal enclosure.

Example 23: The far-edge server chassis of example 22, wherein the internal enclosure further includes interior fins on an interior of the internal enclosure.

Example 24: The far-edge server chassis of example 22 or 23, wherein: the far-edge server chassis further includes an external enclosure surrounding the exterior fins; and the fans are configured to force air between the internal enclosure and the external enclosure.

Example 25: The far-edge server chassis of example 24, wherein the external enclosure is open on an end opposite the fans.

Example 26: The far-edge server chassis of any of examples 19-25, wherein the far-edge server chassis further includes a fluid cap configured to direct one of influent flows or effluent flows from the pumps towards one or more walls of the internal enclosure.

Example 27: The far-edge server chassis of any of examples 19-26, wherein the pumps are disposed within the internal enclosure.

Example 28: The far-edge server chassis of any of examples 19-27, wherein the internal enclosure further includes a pressure relieving device configured to mitigate a pressure differential between an interior of the internal enclosure and an exterior of the internal enclosure.

Example 29: A method comprising: obtaining a far-edge server chassis, the far-edge server chassis including: an internal enclosure; one or more network ports disposed through a wall of the internal enclosure; one or more radio ports disposed through the wall of the internal enclosure; a power port disposed through a wall of the internal enclosure; and one or more fans configured to direct air around the internal enclosure; securing a far-edge server board within the internal enclosure; connecting the network ports, the radio ports, and the power port to the far-edge server board; filling the internal enclosure with a dielectric liquid; and sealing the internal enclosure.

### Terminology

Server, as used herein, may refer to any computer or computing device that receives and/or provides information to clients on a computer network (e.g., wired, fiberoptic, wireless, or some combination thereof). The server may be an application server, a catalog server, a communications server, a computing server, a database server, a storage server, a machine learning server, a predictive analysis server, a fax server, a file server, a game server, a mail server, a media server, a print server, a sound server, a proxy server, a virtual server, a web server, some combination thereof, or a sever serving a different purpose or having a different type of architecture.

The server may include at least one processing unit configured to execute various operations of the server. The processing unit may include one or more processors, one or more central processing units (CPUs), one or more graphics processing units (GPUs), one or more application-specific integrated circuits (ASICs), one or more controllers or microcontrollers, one or more ladder logic controllers, one or more other types of control logic, conventional control systems (e.g., relays, switches, delays) or some combination thereof.

To cool the server, the server may include a cooling system. For example, the server may include a liquid cooling system configured to draw heat from the processing unit. The heat gathered from the processing unit can then be drawn away from the server (e.g., to an outside of a room or building). The cooling system may also, alternatively or additionally, include one or more fans configured to cool components of the server and/or work in conjunction with, or instead of, the liquid cooling system.

When implemented as a liquid cooling system, the cooling system may include one or more drip trays configured to capture leaking coolant from inside the server. The drip trays may be cascading (e.g., an effluent from one becomes an influent for another) and may contain one or more sensors configured to detect whether liquid is within the drip trays.

The liquid cooling system may also contain one or more fluid connections. The fluid connections may include quick-disconnect fittings attached to an external surface of the server. The quick disconnect fittings may be coupled to a heat exchanger within the server (e.g., proximate the processing unit). The fluid connections may be configured to attach to a cooling system or a manifold attached to other servers (e.g., within a same rack, within an adjacent rack, or in some other configuration).

The server may be a standard width (e.g., 19 inches or 21 inches) or a custom dimension. The server may also have any suitable depth. For example, the server may be arranged to not exceed approximately one meter in depth.

The server may contain computer-readable storage memory or media (CRM). The CRM may contain random access memory (RAM), electrically erasable programmable read-only memory (EEPROM), flash memory, one or more disk drives, or some combination thereof. The CRM may contain instructions that cause the processing unit to perform various functions of the server. The CRM may be software, firmware, or some combination thereof. The CRM may also include and/or hold data for the server to use for various functionalities.

The server may also include a power supply configured to supply power to various components within the server. The power supply may be configured to adapt or change incoming power (e.g., alternating current to direct current and/or stepping up or stepping down voltage). Furthermore, the power supply may be configured to supply different power to different components of the server.

The server may include one or more sensors configured to facilitate various functionalities of the server. For example, the sensors may include temperature, humidity, sound, tamper, vibration/shock, and/or moisture sensors. The sensors may also be disposed on an exterior of the server (e.g., on a rack or in a facility proximate the server).

The server may also include one or more clocks. The clocks may enable various functionality of the server to be timed and/or synchronized with another server or computing device.

The server may also include or otherwise be functional to implement one or more alarms. The alarms may be based on any of the sensors above and/or any other logic or instructions executing within the server. For example, the server may be able to notify a surrounding environment (e.g., via an audible tone) or another server or computing device (e.g., a server monitoring system) that a leak has occurred or that the server is overheating.

The server may be a stand-alone unit or may be attached to a server rack. The server rack (or simply rack), may hold any number of servers. Outside of the rack, the server may include a Level 10 assembly. When installed in the rack with one or more other servers, the server may become part of a Level 11 assembly (e.g., rack-level or multi-rack level).

The server may be installed and/or removed from the rack via any means. For example, guide rails may be used to slide the server into and out of the server rack while latches and/or fasteners may be used to secure the server to the server rack.

The rack may contain a centralized heat transfer system configured to draw heat from the servers disposed therein. The heat transfer system may include one or more manifolds directing/gathering liquid coolant to/from the servers. The heat transfer system may also include a side car unit or attach to a facility heat transfer system.

As part of the heat transfer system, the rack may contain one or more drip trays and/or associated systems. For example, the drip trays may contain a set of cascading drip trays and may have one or more alarms based on liquid being within one or more of the trays.

### Conclusion

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. A far-edge server comprising:
an internal enclosure;
one or more wireless-telecom network cards disposed within the internal enclosure;
a dielectric liquid within the internal enclosure;
one or more pumps configured to circulate the dielectric liquid within the internal enclosure;
a network connection configured to communicate with a wireless-telecom network;
a radio connection configured to communicate with at least one remote radio-unit (RRU);
a power connection configured to supply power to the wireless-telecom server; and
one or more fans configured to direct air around the internal enclosure,
wherein the network connection, the radio connection, and the power connection pass through a wall of the internal enclosure.

2. The far-edge server of claim 1, wherein:
the internal enclosure includes one or more seals between an interior of the internal enclosure and an exterior of the internal enclosure; and
the seals are configured to provide at least one of:
international protection (IP) 67 protection; or
network equipment-building system (NEBS) class 4 protection.

3. The far-edge server of claim 1, wherein the fans are proximate a first side of the wireless-telecom server and the network connection, the radio connection, and the power connection are on a second side of the wireless-telecom server.

4. The far-edge server of claim 1, further including exterior fins on an exterior of the internal enclosure.

5. The far-edge server of claim 4, further including interior fins on an interior of the internal enclosure.

6. The far-edge server of claim 4, wherein:
the wireless-telecom server further includes an external enclosure surrounding the exterior fins; and
the fans are configured to force air between the internal enclosure and the external enclosure.

7. The far-edge server of claim 6, wherein the external enclosure is open on an end opposite the fans.

8. The far-edge server of claim 1, wherein the network connection and the radio connection include network ports disposed through a wall of the internal enclosure.

9. The far-edge server of claim 8, wherein the network ports are disposed on the wireless-telecom network cards.

10. The far-edge server of claim 1, wherein the wireless-telecom network cards include a plurality of network cards that are stacked on one another.

11. The far-edge server of claim 1, wherein the wireless-telecom server further includes a processing unit.

12. The far-edge server of claim 11, wherein:
the pumps are disposed within the internal enclosure; and
the processing unit is disposed between the pumps and the wireless-telecom network cards.

13. The far-edge server of claim 11, wherein the wireless-telecom server further includes a fluid cap configured to direct one of influent flows or effluent flows from the pumps towards one or more walls of the internal enclosure and another of the influent flows or the effluent flows across the processing unit.

14. The far-edge server of claim 1, wherein the wireless-telecom server further includes a heater configured to maintain the dielectric liquid above a pre-set temperature.

15. The far-edge server of claim 1, wherein the pumps are disposed within the internal enclosure.

16. The far-edge server of claim 1, wherein the internal enclosure further includes a pressure relieving device configured to mitigate a pressure differential between an interior of the internal enclosure and an exterior of the internal enclosure.

17. The far-edge server of claim 1, wherein the radio connection includes one or more fiber-optic connections.

18. The far-edge server of claim 1, wherein:
the wireless-telecom server includes an internal temperature probe; and
the wireless-telecom server is configured to control the pumps and the fans based on information received from the internal temperature probe.

19. A far-edge server chassis comprising:
an internal enclosure configured to contain:
a wireless-telecom server board;
a dielectric liquid;
one or more pumps configured to circulate the dielectric liquid within the internal enclosure;
one or more network ports disposed through a wall of the internal enclosure;
one or more radio ports disposed through the wall of the internal enclosure;
a power port disposed through a wall of the internal enclosure; and
one or more fans configured to direct air around the internal enclosure.

20. A method comprising:
obtaining a far-edge server chassis, the far-edge server chassis including:
an internal enclosure;
one or more network ports disposed through a wall of the internal enclosure;
one or more radio ports disposed through the wall of the internal enclosure;
a power port disposed through a wall of the internal enclosure; and
one or more fans configured to direct air around the internal enclosure;
securing a wireless-telecom server board within the internal enclosure;
connecting the network ports, the radio ports, and the power port to the wireless-telecom server board;
filling the internal enclosure with a dielectric liquid; and
sealing the internal enclosure.
